(19) United States
(12) Patent Application Publication
(10) Pub. No.: US 2023/0068101 A1
(43) Pub. Date: Mar. 2, 2023

(54) SUBSTRATE PROCESSING APPARATUS INCLUDING IMPEDANCE ADJUSTER

(71) Applicant: ASM IP Holding B.V., Almere (NL)

(72) Inventor: Tomohiro Arakawa, Sagamihara-shi (JP)

(21) Appl. No.: 17/897,461

(22) Filed: Aug. 29, 2022

Related U.S. Application Data
(60) Provisional application No. 63/239,802, filed on Sep. 1, 2021.

(51) Int. Cl. H01J 37/32; C23C 16/505; C23C 16/455

(52) U.S. Cl. CPC H01J 37/32183; H01J 37/32091; H01J 37/321; C23C 16/505; C23C 16/45565; H01J 2237/332

(57) ABSTRACT

A substrate processing apparatus is disclosed. An exemplary substrate processing apparatus includes a reaction chamber; a susceptor positioned within the reaction chamber to be constructed and arranged to support a substrate; a shower plate to be constructed and arranged to face the susceptor; and an RF generator electrically coupled to the shower plate via an RF plate, with the susceptor electrically grounded; wherein the RF plate is provided with a plurality of impedance adjusters.

### CROSS-REFERENCE TO RELATED APPLICATIONS

This application claims priority to U.S. Provisional Patent Application Ser. No. 63/239,802 filed Sep. 1, 2021 titled SUBSTRATE PROCESSING APPARATUS INCLUDING IMPEDANCE ADJUSTER, the disclosure of which is hereby incorporated by reference in its entirety.

### FIELD OF INVENTION

The present disclosure relates generally to a substrate processing apparatus. More particularly, exemplary embodiments of the present disclosure relate to a substrate processing apparatus including an impedance adjuster.

### BACKGROUND OF THE DISCLOSURE

Reaction chambers are used for processing a substrate therein (e.g., depositing various material layers onto semiconductor substrates). A substrate is placed on a susceptor inside a reaction chamber. FIG. 1 is a cross-sectional perspective view showing an example of a substrate processing apparatus. An exemplary substrate processing apparatus is disclosed in U.S. patent application Ser. No. 17/039,874, which is hereby incorporated by reference. This substrate processing apparatus has a parallel plate structure including a susceptor 10 and a shower plate 14. The shower plate 14 is provided with a plurality of holes such that gas is supplied to a substrate placed on the susceptor 10, causing the deposition of a thin film on the substrate. The shower plate 14 is mounted on an exhaust duct 12 via an O-ring (not shown).

A relay ring 18 is placed on an upper body 16 and shower plate 14. An RF plate 20 is connected to the relay ring 18. An RF power is applied to the shower plate 14 via the RF plate 20 and the relay ring 18, creating an RF plasma between the shower plate 14 and the susceptor 10.

The deposition or other processing on the surface of a substrate may have a desired pattern. For example, it may be desired to have a layer(s) of deposited material on a substrate with a uniform thickness across the substrate surface. In other words, an even deposition of material may be desirable. However, in some instances, it may be desired that the material deposition at or proximate to one portion of a substrate be different than the deposition on another portion of the substrate. Accordingly, apparatus and methods are therefore desirable that allow the ability to adjust the amount of processing on a substrate in certain areas of the substrate (e.g., for facilitating more even and/or uniform deposition on a surface of a substrate).

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a substrate processing apparatus is provided. The substrate processing apparatus may comprise a reaction chamber; a susceptor positioned within the reaction chamber to be constructed and arranged to support a substrate; a shower plate to be constructed and arranged to face the susceptor; and an RF generator electrically coupled to the shower plate via an RF plate, with the susceptor electrically grounded; wherein the RF plate is provided with a plurality of impedance adjusters.

In various embodiments, the RF plate may be a ring-shaped structure.

In various embodiments, the impedance adjustors may be provided every 90 degrees on the RF plate.

In various embodiments, the impedance adjusters may comprise at least one of a capacitor and an inductor.

In various embodiments, the impedance adjusters may be resonance circuits.

In various embodiments, the capacitor may comprise an adjustable capacitance and the inductor may comprise an adjustable inductance.

In various embodiments, the shower plate may be provided with a plurality of holes for supplying gas to the substrate.

In various embodiments, a matching box may be disposed between the RF generator and the RF plate.

In various embodiments, a relay ring may be disposed between the shower plate and the impedance adjusters.

In various embodiments, a substrate processing apparatus may comprise one or more reaction chamber modules, each reaction chamber module comprising two or more reaction stations; a susceptor positioned within each reaction station to be constructed and arranged to support a substrate; a shower plate positioned within each station to be constructed and arranged to face the susceptor; and an RF generator electrically coupled in RF power providing communication to the shower plate via an RF plate, with the susceptor electrically grounded; wherein the RF plate is provided with a plurality of impedance adjusters.

In various embodiments, a substrate processing method may comprise placing a substrate on a susceptor; generating plasma between a shower plate and the susceptor by applying a high frequency power to the shower plate while providing a gas between the shower plate and the susceptor from the shower plate facing the susceptor; wherein the high frequency power is supplied to the shower plate through a plurality of impedance adjusters.

In various embodiments, the high frequency power may comprise a frequency of 13.56 MHz or more.

In various embodiments, a method may comprise adjusting an impedance of a first impedance adjuster; adjusting a first electric field proximate a first part of a shower plate coupled to the first impedance adjuster in response to the impedance of the first impedance adjuster; adjusting an impedance of a second impedance adjuster; and adjusting a second electric field proximate a second part of the shower plate coupled to the second impedance adjuster in response to the impedance of the second impedance adjuster.

For the purpose of summarizing the disclosure and the advantages achieved over the prior art, certain objects and advantages of the disclosure have been described herein above. Of course, it is to be understood that not necessarily all such objects or advantages may be achieved in accordance with any particular embodiment of the disclosure. Thus, for example, those skilled in the art will recognize that the embodiments disclosed herein may be carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 is a cross-sectional perspective view showing an example of a substrate processing apparatus.

FIG. 2 is a cross-sectional view of an exemplary substrate processing apparatus in accordance with various embodiments.

FIG. 3 is a cross-sectional top view of an exemplary substrate processing apparatus in accordance with various embodiments.

FIG. 4A is a schematic diagram of an exemplary substrate processing apparatus including impedance adjusters in accordance with various embodiments.

FIG. 4B is a schematic diagram of a substrate processing apparatus including impedance adjusters in accordance with various embodiments.

FIG. 4C is a schematic diagram of a substrate processing apparatus including impedance adjusters in accordance with various embodiments.

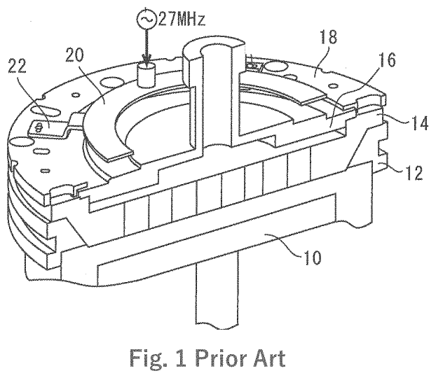

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

In this disclosure, “gas” may include material that is a gas at normal temperature and pressure, a vaporized solid and/or a vaporized liquid, and may be constituted by a single gas or a mixture of gases, depending on the context. A gas other than the process gas, i.e., a gas introduced without passing through a gas supply unit, such as a shower plate, or the like, may be used for, e.g., sealing the reaction space, and may include a seal gas, such as a rare or other inert gas. The term inert gas refers to a gas that does not take part in a chemical reaction to an appreciable extent and/or a gas that can excite a precursor when plasma power is applied. The terms precursor and reactant can be used interchangeably.

As used herein, the term “substrate” may refer to any underlying material or materials that may be used, or upon which, a device, a circuit, or a film may be formed.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

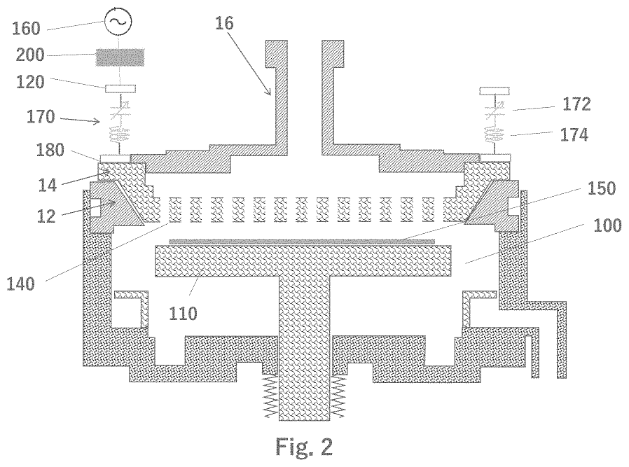

FIG. 2 is a cross-sectional view of a substrate processing apparatus in an embodiment of the present invention. The substrate processing apparatus comprises a reaction chamber 100; a susceptor 110 positioned within the reaction chamber 100 and configured to support a substrate 150; a shower plate 140 configured to face the susceptor 110; and an RF generator 160 electrically coupled to the shower plate 140 via an RF plate 120, such that the susceptor 110 is electrically grounded. The RF plate 120 is provided with a plurality of impedance adjusters 170.

Applying high radio frequency (“HRF”) power (for example, 13.56 MHz or 27 MHz) to the shower plate 140 may excite a plasma between the shower plate 140 and the susceptor 110. A temperature regulator may be provided in the susceptor 110 to maintain a constant temperature of the substrate. The shower plate 140 may be provided with a plurality of holes for supplying gas to the substrate 150.

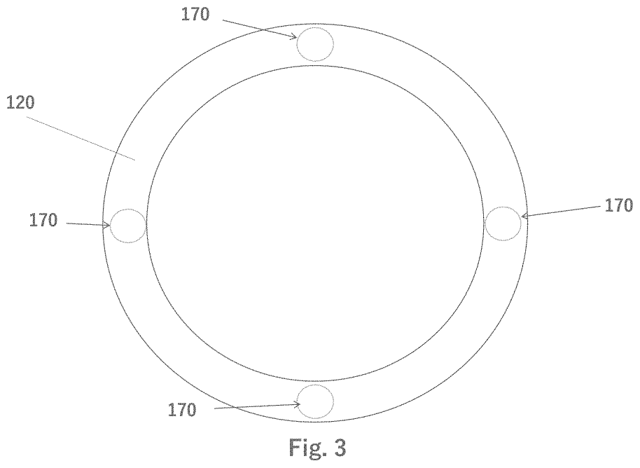

FIG. 3 is a cross-sectional top view of an exemplary substrate processing apparatus. The RF plate 120 may be a ring-shaped structure. The impedance adjustors 170 may be provided every 90 degrees on the RF plate 120. Other embodiments may be possible where the impedance adjustors 170 are provided every 60 degrees on the RF plate 120, for example, or at other intervals along the RF plate 120. Additional impedance adjustors 170 along the RF plate 120 may allow for additional control of the impedance along the entirety of the RF plate 120.

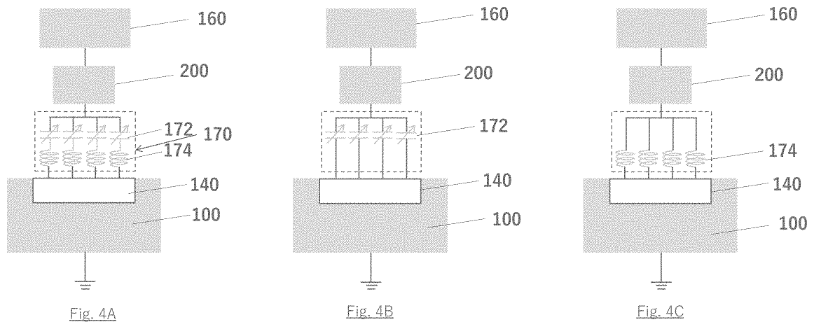

FIGS. 4A to 4C are schematic diagrams of exemplary substrate processing apparatuses including impedance adjusters. The impedance adjusters 170 may comprise at least one of a capacitor 172 and an inductor 174, whereby a resonance circuit may be formed if the impedance adjusters 170 include both the capacitor 172 and the inductor 174. The capacitor 172 may comprise an adjustable capacitance and the inductor 174 may comprise an adjustable inductance. FIG. 4A illustrates an example embodiment where the impedance adjuster 170 comprises both the capacitor 172 and the inductor 174. FIG. 4B illustrates an example embodiment where the impedance adjuster 170 comprises just the capacitor 172. FIG. 4C illustrates an example embodiment where the impedance adjuster 170 comprises just the inductor 174.

With reference to FIG. 2, a matching box 200 may be disposed between the RF generator 160 and the RF plate 120. The matching box 200 may generate an impedance that matches the internal impedance of the reaction chamber 100 to an impedance of the RF generator 160. Further, a relay ring 180 may be disposed between the shower plate 140 and the impedance adjusters 170 to transmit RF power to the shower plate 140.

During substrate processing (e.g., during atomic layer deposition (ALD), chemical vapor deposition (CVD), and/or the like), an electric field may form around the susceptor 110 as electrons travel from the shower plate 140 to the susceptor. The electric field around different portions of the susceptor 110 may differ, causing differing processing results on different portions of the substrate 150 corresponding to the different proximate electric fields. To avoid the difference, the impedance of the resonance circuit 170 may be adjusted. Adjusting the impedance of the resonance circuit 170 may adjust the electricity flow through the shower plate 140. For example, to adjust the impedance of the resonance circuit 170, the inductance of an inductor in a resonance circuit may be adjusted, and/or the capacitance of a capacitor in a resonance circuit may be adjusted. As a further example, to adjust the electric field around one portion of the shower plate 140, the capacitance of one of the four capacitors may be adjusted. By so doing, the impedance of one of the four resonance circuits may be adjusted, thereby changing the electricity flow. In addition, adjusting the impedance may result in a more uniform film deposited on the substrate 150.

In some embodiments, a multiple chamber module (two or four chambers or stations for processing substrates disposed close to each other) may be used, wherein a reactant gas may be supplied through a shared line whereas a precursor gas may be supplied through unshared lines.

A skilled artisan will appreciate that the apparatus includes one or more controller(s) programmed or otherwise configured to cause the deposition and reactor cleaning processes described elsewhere herein to be conducted. The controller(s) may be communicated with the various power sources, heating systems, pumps, robotics, and gas flow controllers or valves of the reactor, as will be appreciated by the skilled artisan.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A substrate processing apparatus, comprising:
a reaction chamber;
a susceptor positioned within the reaction chamber to be constructed and arranged to support a substrate; a shower plate to be constructed and arranged to face the susceptor; and an RF generator electrically coupled to the shower plate via an RF plate, with the susceptor electrically grounded;
wherein the RF plate is provided with a plurality of impedance adjusters.

2. The substrate processing apparatus according to claim 1, wherein the RF plate is a ring-shaped structure.

3. The substrate processing apparatus according to claim 2, wherein the impedance adjustors are provided every 90 degrees on the RF plate.

4. The substrate processing apparatus according to claim 1, wherein the impedance adjusters comprise at least one of a capacitor and an inductor.

5. The substrate processing apparatus according to claim 4, wherein the impedance adjusters are resonance circuits.

6. The substrate processing apparatus according to claim 4, wherein the capacitor comprises an adjustable capacitance and the inductor comprises an adjustable inductance.

7. The substrate processing apparatus according to claim 1, wherein the shower plate is provided with a plurality of holes for supplying gas to the substrate.

8. The substrate processing apparatus according to claim 1, further comprising a matching box disposed between the RF generator and the RF plate.

9. The substrate processing apparatus according to claim 1, further comprising a relay ring disposed between the shower plate and the impedance adjusters.

10. A substrate processing apparatus comprising:
one or more reaction chamber modules, each reaction chamber module comprising two or more reaction stations;
a susceptor positioned within each reaction station to be constructed and arranged to support a substrate;
a shower plate positioned within each station to be constructed and arranged to face the susceptor; and
an RF generator electrically coupled in RF power providing communication to the shower plate via an RF plate, with the susceptor electrically grounded;
wherein the RF plate is provided with a plurality of impedance adjusters.

11. A substrate processing method comprising:
placing a substrate on a susceptor;
generating plasma between a shower plate and the susceptor by applying a high frequency power to the shower plate while providing a gas between the shower plate and the susceptor from the shower plate facing the susceptor;
wherein the high frequency power is supplied to the shower plate through a plurality of impedance adjusters.

12. The substrate processing method according to claim 11, wherein the high frequency power comprises a frequency of 13.56 MHz or more.

13. A method, comprising:
adjusting an impedance of a first impedance adjuster;
adjusting a first electric field proximate a first part of a shower plate coupled to the first impedance adjuster in response to the impedance of the first impedance adjuster;
adjusting an impedance of a second impedance adjuster; and
adjusting a second electric field proximate a second part of the shower plate coupled to the second impedance adjuster in response to the impedance of the second impedance adjuster.
